(19) United States
(12) Patent Application Publication
(10) Pub. No.: US 2025/0306316 A1
(43) Pub. Date: Oct. 2, 2025

(54) INTEGRATED PHOTONICS CIRCUITRY

(71) Applicant: Advanced Micro Devices, Inc., Santa Clara, CA (US)

(72) Inventor: Deepak Vasant KULKARNI, Austin, TX (US)

(21) Appl. No.: 18/620,831

(22) Filed: Mar. 28, 2024

(51) Int. Cl. G02B 6/42; H01L 23/00; H01L 23/15; H01L 23/498; H01L 23/538; H01L 25/065

(52) U.S. Cl. CPC G02B 6/4287; G02B 6/4214; H01L 23/15; H01L 23/49816; H01L 23/5381; H01L 24/16; H01L 24/32; H01L 24/73; H01L 25/0652; H01L 2224/16146; H01L 2224/16225; H01L 2224/3201; H01L 2224/32111; H01L 2224/73203; H01L 2924/04694; H01L 2924/1431; H01L 2924/15311; H01L 2924/182; H01L 2924/19102

(57) ABSTRACT

Examples herein describe integrated photonics circuitry. The integrated photonics circuitry includes an interposer structure mounted on a substrate, a glass chiplet of the interposer structure, and an electrical and photonic integrated circuit (EPIC). The EPIC has a first portion disposed on the glass chiplet and a second portion disposed over the substrate. The glass chiplet includes a waveguide. The waveguide is coupled to the EPIC.

### TECHNICAL FIELD

Examples of the present disclosure generally relate to integrated circuit packages, and more specifically, to integrated photonics circuitry.

### BACKGROUND

Incorporating optical components into electronic integrated circuit (IC) packages used in applications that process very large amounts of data such as large language models may overcome some of the current limitations of the electronic IC packages due to the latency and bandwidth advantages of photonics. However, integrated photonics is challenging from a fabrication perspective because the optical components require precise alignments and can easily become misaligned during various fabrication processes. Additional challenges to integrated photonics include excess energy consumption as a result of long electrical routes through the packaging and challenges related to interconnection with optical fibers due to size mismatches, mode matching, losses at interfaces, etc.

### SUMMARY

Integrated photonics circuitry is described in some embodiments. The integrated photonics circuitry includes an interposer structure mounted on a substrate, a glass chiplet of the interposer structure, and an electrical and photonic integrated circuit (EPIC). The EPIC has a first portion disposed on the glass chiplet and a second portion disposed over the substrate. A waveguide of the glass chiplet is coupled to the EPIC.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates integrated photonics circuitry, according to an example.

FIGS. 2A, 2B, 2C, and 2D illustrate a process for fabricating integrated photonics circuitry, according to an example.

FIG. 3 illustrates integrated photonics circuitry implemented using an alternative waveguide configuration, according to an example.

FIG. 4 is a flow diagram depicting a method for fabricating integrated photonics circuitry, according to an example.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Integrating photonics circuitry into electronic integrated circuits (ICs) is challenging because processes and conditions used to fabricate the electronic components can damage or misalign the optical components. Additionally, processes used to fabricate the optical components are typically performed for each IC whereas the electronic components are normally fabricated in large batches. For example, chemicals/temperatures used in etching/deposition processes for fabricating the electronic components can damage or cause variation in optical properties of the optical components. Moreover, the optical components require precise alignments between ends of optical fibers to minimize losses at the optical fiber interfaces. These precise alignments are often performed using “v-groove” alignment/attachment techniques (the grooves guide the ends of the optical fibers for the alignment/attachment) that are difficult to perform in between batch process steps for fabricating the electronic components.

Examples herein describe integrated photonics circuitry including an interposer structure and a glass chiplet of the interposer structure. In some examples, the interposer structure is mounted on a substrate. In various embodiments, the glass chiplet includes a waveguide which can be prefabricated. For instance, the waveguide may be fabricated in the glass chiplet using ion exchange, laser writing, reactive ion etching, etc. In some examples, the glass chiplet is included in the interposer structure in a late attach step of a process of fabricating the integrated photonics circuitry so that the waveguide is not damaged in earlier steps of the process that may utilize chemicals and/or high temperatures.

In one or more embodiments, an electrical and photonic integrated circuit (EPIC) has a first portion and a second portion. The second portion is disposed over the substrate. The first portion is disposed on the glass chiplet such that the EPIC is coupled to the waveguide of the glass chiplet. For instance, the first portion of the EPIC is coupled (evanescently coupled, edge coupled, etc.) to the waveguide. In a first example, the waveguide is disposed in a top portion of the glass chiplet and a bottom portion of the EPIC is coupled to the waveguide. In a second example, the waveguide is disposed in an upper portion of an “L” shaped feature of the glass chiplet, and a side portion of the EPIC is coupled to the waveguide.

In examples in which the EPIC is evanescently coupled to the waveguide of the glass chiplet, an evanescent field of a waveguide included in the EPIC interacts with an evanescent field of the waveguide of the glass chiplet. This interaction facilitates transfer of energy and/or information between the waveguide of the glass chiplet and the waveguide of the EPIC. Notably, an optical fiber can be coupled to the waveguide of the glass chiplet, and an optical signal output from the optical fiber may be transmitted to the EPIC via the evanescent coupling. In some embodiments, electrical components and photonic components of the EPIC can convert the optical signal to an electrical signal for communication to a processor of the integrated photonics circuitry.

In various embodiments, the processor can include a central processing unit (CPU), a graphics processing unit (GPU), an accelerator, multiple processors, etc. The processor is attached to the interposer structure via a silicon bridge of the interposer structure. A plurality of dielectric electric layers are disposed over the silicon bridge having routing circuitry formed therethrough. For example, the processor and the EPIC are communicatively coupled within the silicon bridge and via the routing circuitry.

The described integrated photonics circuitry is scalable to wafers or panels, and does not rely on “v-groove” alignment/attachment techniques for ends of optical fibers. Instead, an optical fiber can be coupled to the waveguide of the glass chiplet to integrate optics into 2.5D packaging architectures. As part of a late attach step in fabricating the integrated photonics circuitry, the waveguide of the glass chiplet is immune from damages which can be caused by earlier steps in the fabrication process. Additionally, the waveguide is supported by multiple molds and underfill epoxies which prevent misalignment of the evanescent or edge coupling.

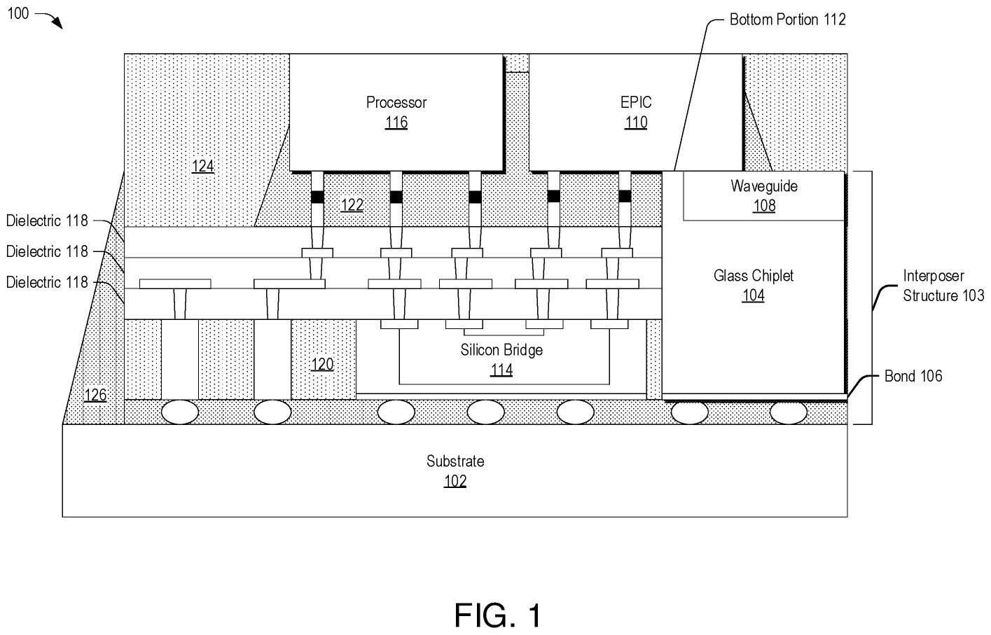

FIG. 1 illustrates integrated photonics circuitry 100, according to an example. In one or more embodiments, the integrated photonics circuitry 100 includes a substrate 102, and an interposer structure 103 may be mounted on the substrate 102. The interposer structure 103 generally includes the entire interconnect structure between the IC dies (116, 110 later discussed below) and the substrate 102. For example, the interposer structure 103 may include glass, organic material, silicon bridges, redistribution layers, silicon interposers, etc. A glass chiplet 104 is fixed within the interposer structure 103 via a bond 106. In some examples, the bond 106 includes a die attach adhesive or die attach tape. In other examples, the bond 106 can include a variety of different mechanisms or materials (e.g., solder, epoxy, etc.) configured to fix the glass chiplet 104 within the interposer structure 103, for example, as part of a late attach process in fabricating the integrated photonics circuitry 100.

The glass chiplet 104 includes a waveguide 108 which is an optical waveguide configured to efficiently receive and transmit light waves such that transmission losses are minimized. In some embodiments, the waveguide 108 is manufactured in the glass chiplet 104 using an ion exchange process in which some ions are diffused into the glass chiplet 104 and exchanged with other ions to selectively alter a refractive index of the glass chiplet 104 in the location of the waveguide 108. In other embodiments, the waveguide 108 may be manufactured/fabricated in the glass chiplet 104 using other techniques such as reactive ion etching, femtosecond laser writing, plasma-enhanced chemical vapor deposition, etc.

In various embodiments, the integrated photonics circuitry 100 includes an electrical and photonic integrated circuit (EPIC) 110. A bottom portion 112 of the EPIC 110 is disposed over the waveguide 108, and the EPIC 110 is attached to the interposer structure 103 via a silicon bridge 114 of the interposer structure 103. In the example illustrated in FIG. 1, the EPIC 110 includes both electronic components and photonic components which are capable of generating, receiving/detecting, manipulating, and/or transmitting electrical signals and optical signals, respectively. However, in some examples, the EPIC 110 can be implemented as a photonic integrated circuit (PIC) including the photonic components such that the electronic components are disposed in another location within the integrated photonics circuitry 100 and the electronic components are available to the PIC via the silicon bridge 114. For instance, the silicon bridge 114 may be an interconnect die which is part of an elevated fan-out bridge of the integrated photonics circuitry 100.

As shown in FIG. 1, the waveguide 108 is coupled to the bottom portion 112 of the EPIC 110. In one or more embodiments, the waveguide 108 is evanescently coupled to the EPIC 110. For instance, the EPIC 110 also includes a waveguide and an evanescent field (e.g., an electromagnetic field) of this waveguide partially extends into (overlaps with) an evanescent field of the waveguide 108 such that the evanescent field of the waveguide of the EPIC 110 partially extends into the waveguide 108. Similarly, the evanescent field of the waveguide 108 partially extends into the waveguide of the EPIC 110. As a result of this evanescent coupling, energy or information can be transferred between the waveguide 108 and the EPIC 110.

A processor 116 of the integrated photonics circuitry 100 is also illustrated to be coupled to the interposer structure 103 via the silicon bridge 114 and disposed adjacent to the EPIC 110. In various embodiments, the processor 116 can include a central processing unit (CPU), a graphics processing unit (GPU), an accelerator, etc. In some embodiments, the processor 116 includes multiple processors such as a CPU and a GPU.

In one or more embodiments, dielectrics 118 may be disposed between the processor 116 and the silicon bridge 114 and the dielectrics 118 can also be disposed between the EPIC 110 and the silicon bridge 114. Routing circuitry may be formed within the dielectrics 118 which electrically connects the processor 116 and the EPIC 110. In various embodiments, the dielectrics 118 are polymer dielectrics. For example, the dielectrics 118 may be polyimide dielectrics.

Notably, in some examples, the EPIC 110 and the processor 116 are communicatively coupled via a first connection/interface of the silicon bridge 114. The EPIC 110 and the processor 116 can also be communicatively coupled via a second connection/interface of the silicon bridge 114. In some embodiments, an optical fiber may be coupled to the waveguide 108; an optical signal can be transmitted through the optical fiber and the waveguide 108 to the EPIC 110 via the evanescent coupling; the optical signal can be converted to an electrical signal by the electronic components and the photonic components of the EPIC 110; and the electrical signal may be transmitted to the processor 116 via the silicon bridge 114. In various embodiments, the optical fiber can be coupled to the waveguide 108; the processor 116 may execute instructions to cause an additional electrical signal to be transmitted to the EPIC 110 via the silicon bridge 114; the additional electrical signal can be converted to an additional optical signal by the electronic components and the photonic components of the EPIC 110; and the additional optical signal may be transmitted through the waveguide 108 via the evanescent coupling and to the optical fiber coupled to the waveguide 108.

In some examples, the integrated photonics circuitry 100 includes a first mold 120 (e.g., mold material) disposed between the EPIC 110 and the substrate 102 such that the dielectrics 118 are disposed between the first mold 120 and the EPIC 110. For example, the silicon bridge 114 may be circumscribed by the first mold 120. In one or more embodiments, the integrated photonics circuitry 100 includes a first underfill epoxy 122 disposed between the EPIC 110 and the interposer structure 103. In the example illustrated in FIG. 1, the processor 116 and the EPIC 110 are partially disposed in a second mold 124 (e.g., mold material) such that the glass chiplet 104 is disposed between the second mold 124 and the substrate 102. In various examples, the integrated photonics circuitry 100 includes a second underfill epoxy 126 disposed around and/or above the interposer structure 103. The first mold 120, the first underfill epoxy 122, the second mold 124, and the second underfill epoxy 126 may be configured to provide mechanical stability and/or warpage control for the integrated photonics circuitry 100.

For instance, by coupling the waveguide 108 of the glass chiplet 104 to the EPIC 110, the integrated photonics circuitry 100 facilitates pluggable optics into a 2.5D packaging architecture that includes the interposer structure 103. Furthermore, the pluggable optics are facilitated without relying on v-groove alignment to couple optical fibers. In some examples, the glass chiplet 104 may be incorporated into the integrated photonics circuitry 100 as a “late attachment” in the process of fabricating the integrated photonics circuitry 100 such that the glass chiplet 104 is not exposed to forces (e.g., misalignments) and other hazards (e.g., chemicals) from earlier stages of fabrication. The integrated photonics circuitry 100 is also scalable to wafer based and/or panel based processes.

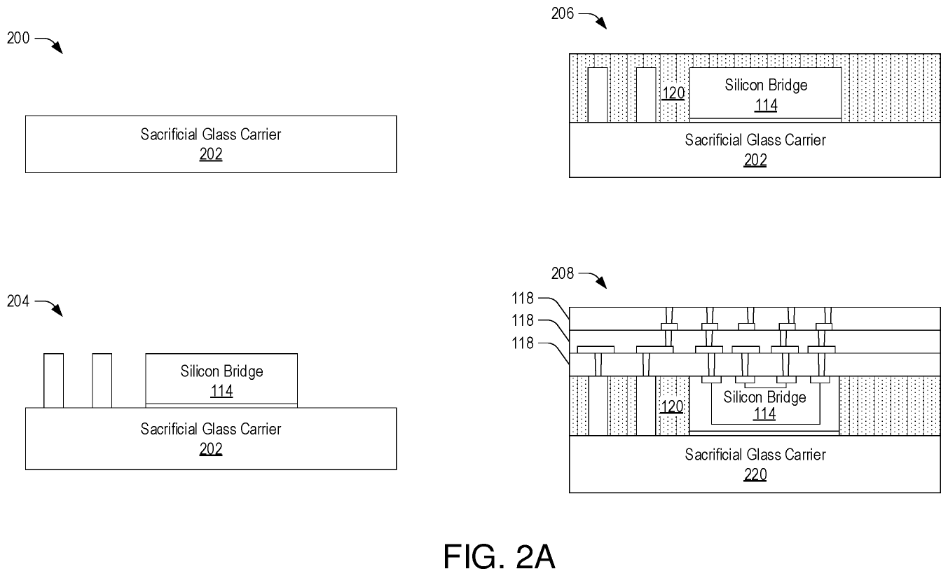

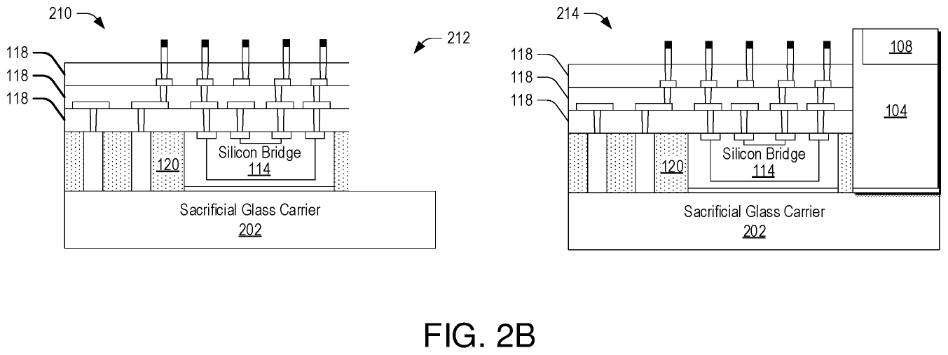

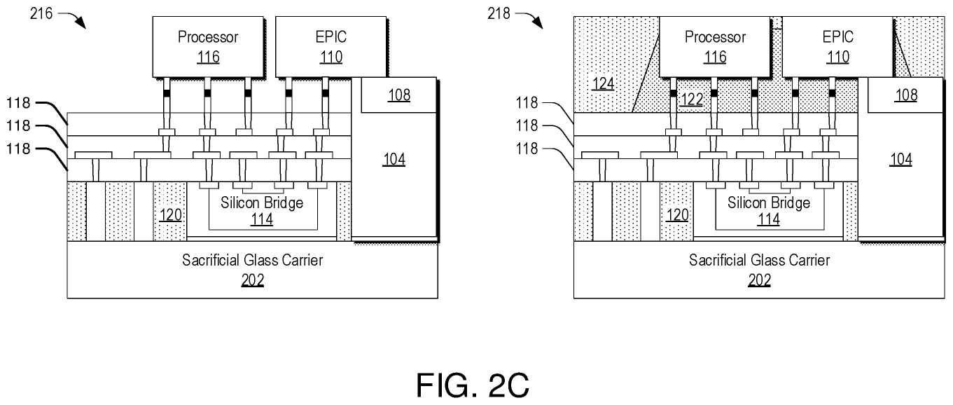

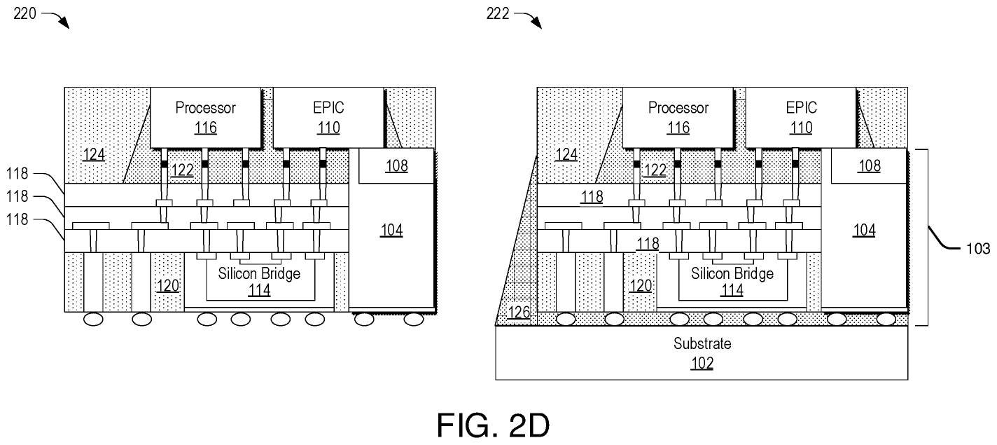

FIGS. 2A, 2B, 2C, and 2D illustrate a process for fabricating integrated photonics circuitry, according to an example. FIG. 2A depicts an initial stage 200 of fabricating the integrated photonics circuitry 100 which includes a sacrificial glass carrier 202. FIG. 2A also depicts a first stage 204 of the fabrication. In the first stage 204, the silicon bridge 114 is disposed over the sacrificial glass carrier 202. Electrically conductive pillars (e.g., copper pillars) are also disposed over the sacrificial glass carrier 202. In some examples, the electrically conductive pillars will eventually become connections between a top die and the substrate 102. In one or more embodiments, the electrically conductive pillars are capable of electrically connecting the routing circuitry of the dielectrics 118 to circuitry of the substrate 102.

At a second stage 206 of the fabrication, the first mold 120 is molded over the electrically conductive pillars, the silicon bridge 114, and the sacrificial glass carrier 202. As shown in FIG. 2A, a top portion of the first mold 120 is then removed (e.g., by grinding the top portion, etching the top portion, etc.) in order to expose top portions of the electrically conductive pillars and the silicon bridge 114. After removing the top portion of the first mold 120, the dielectrics 118 are disposed over the exposed top portions of the electrically conductive pillars and the silicon bridge 114 at a third stage 208 of fabricating the integrated photonics circuitry 100.

FIG. 2B depicts a fourth stage 210 of the fabrication. At the fourth stage 210, a cavity 212 is formed for the glass chiplet 104. In various embodiments, the cavity 212 is formed by etching, grinding, and/or laser cutting through the dielectrics 118 and the first mold 120 to remove a portion of the dielectrics 118 and a portion of the first mold 120 from the sacrificial glass carrier 202. Additionally, solder bumps are added above the dielectrics in the fourth stage 210. In some embodiments, the solder bumps will form electrical connections between the EPIC 110 and the silicon bridge 114 and the solder bumps will also form electrical connections between the processor 116 and the silicon bridge 114.

At a fifth stage 214 of fabricating the integrated photonics circuitry 100, the glass chiplet 104 is disposed in the cavity 212. In some examples, the first mold 120 contacts a side of the glass chiplet 104. In some embodiments, the glass chiplet 104 is disposed in the cavity 212 such that a portion of the waveguide 108 extends above the solder bumps. For example, the extension of the portion of the waveguide 108 above the solder bumps is configured to evanescently couple the waveguide 108 to the EPIC 110 when the EPIC 110 is disposed over the solder bumps.

FIG. 2C illustrates a sixth stage 216 of the fabrication. As shown, in the sixth stage 216, the processor 116 is disposed over some of the solder bumps to form the electrical connections between the processor 116 and the silicon bridge 114 and the EPIC 110 is disposed over some of the solder bumps to form the electrical connections between the EPIC 110 and the silicon bridge 114. In various embodiments, disposing the EPIC 110 over the solder bumps also couples the EPIC 110 and the waveguide 108.

In some examples, the solder bumps facilitate a coupling between the EPIC 110 and the waveguide 108 which causes the EPIC 110 and the waveguide 108 to be evanescently coupled. For instance, the solder bumps can be slightly compressed or slightly extended (e.g., by adding additional solder to the solder bumps) in order to efficiently couple the EPIC 110 and the waveguide 108 such that substantially no air gap is disposed between the EPIC 110 and the waveguide 108. In one or more embodiments, electrically conductive portions of the EPIC 110 which connect to the solder bumps can provide some mechanical compliance (e.g., extension or compression) to further facilitate the efficient coupling of the EPIC 110 and the waveguide 108 even in scenarios in which some of the solder bumps are slightly longer than other ones of the solder bumps. By efficiently coupling the EPIC 110 and the waveguide 108 in this manner, photon loss at an interface between the EPIC 110 and the waveguide 108 is mitigated/minimized.

FIG. 2C also depicts a seventh stage 218 of fabricating the integrated photonics circuitry 100. At the seventh stage 218, the first underfill epoxy 122 is added between the processor 116 and the dielectrics 118 and added between the EPIC 110 and the dielectrics 118. The second mold 124 is also molded over the waveguide 108, the EPIC 110, and the processor 116. In some embodiments, a top portion of the second mold 124 is then removed by grinding and/or etching to expose top portions of the processor 116 and the EPIC 110.

FIG. 2D depicts an eighth stage 220 of the fabrication. At the eighth stage 220, the sacrificial glass carrier 202 is debonded and removed from the assembly, and bumps are deposited in place of the sacrificial glass carrier 202. The bumps can be electrical conductors such as solder bumps which form electrical and mechanical interfaces with the substrate 102. At a ninth stage 222 of fabricating the integrated photonics circuitry 100, the solder bumps are disposed over the substrate 102 and the second underfill epoxy 126 is added to fix the substrate 102 to the bumps and to provide mechanical stability for the integrated photonics circuitry 100. As shown in FIG. 2D, the waveguide 108 is coupled to the bottom portion 112 of the EPIC 110, and the glass chiplet 104 is secured (e.g., prevented from actuating) relative to the EPIC 110 by the first mold 120, the first underfill epoxy 122, the second mold 124, and the second underfill epoxy 126.

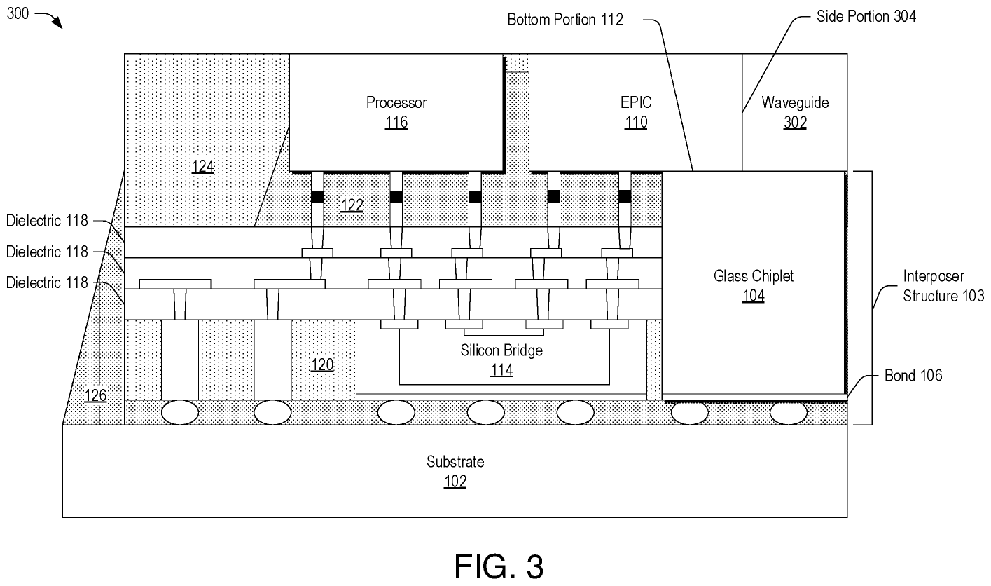

FIG. 3 illustrates integrated photonics circuitry 100 implemented using an alternative waveguide configuration 300, according to an example. In the alternative waveguide configuration 300, a waveguide 302 of the glass chiplet 104 is coupled (e.g., evanescently coupled, edge coupled, etc.) to a side portion 304 of the EPIC 110. Similar to the example described with respect to FIG. 1, the waveguide 302 may be evanescently coupled to the EPIC 110. For example, the waveguide of the EPIC 110 is disposed along the right side portion of the EPIC 110 in the alternative waveguide configuration 300 and the waveguide of the EPIC 110 is disposed along the bottom portion 112 of the EPIC 110 in the example illustrated in FIG. 1.

As shown in FIG. 3, the bottom portion 112 of the EPIC 110 is coupled to a top portion of the glass chiplet 104 such that an interface between the EPIC 110 and the waveguide 302 is evanescently coupled and an interface between the EPIC 110 and the top portion of the glass chiplet 104 is mechanically coupled. In some embodiments, the alternative waveguide configuration 300 may provide an increased surface area between the EPIC 110 and the waveguide 302 forming the evanescent coupling relative to a surface area between the EPIC 110 and the waveguide 108 forming the evanescent coupling. In one or more embodiments, the evanescent coupling between the EPIC 110 and the waveguide 302 in the alternative waveguide configuration 300 may have a greater mechanical stability than the evanescent coupling between the EPIC 110 and the waveguide 108 described with respect to FIG. 1.

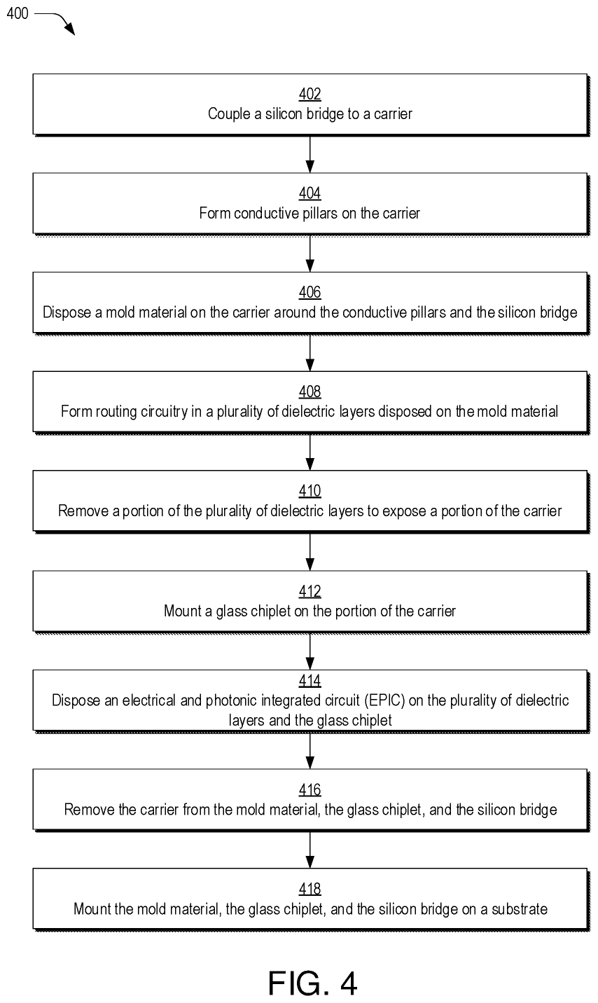

FIG. 4 is a flow diagram depicting a method 400 for fabricating integrated photonics circuitry, according to an example. At 402, a silicon bridge is coupled to a carrier. In one or more embodiments, the silicon bridge 114 is coupled to the sacrificial glass carrier 202. At 404, conductive pillars are formed on the carrier. In various embodiments, conductive pillars are formed on the sacrificial glass carrier 202.

At 406, a mold material is disposed on the carrier around the conductive pillars and the silicon bridge. In certain embodiments, the first mold 120 is disposed on the sacrificial glass carrier 202 around the conductive pillars and the silicone bridge 114. A 408, routing circuitry is formed in a plurality of dielectric layers disposed on the mold material. In some embodiments, routing circuitry is formed in the dielectrics 118 disposed on the first mold 120.

At 410, a portion of the plurality of dielectric layers is removed to expose a portion of the carrier. In one or more embodiments, a portion of the dielectrics 118 and a portion of the first mold 120 are removed from the sacrificial glass carrier 202 to form the cavity 212. At 412, a glass chiplet is mounted on the portion of the carrier. In various embodiments, the glass chiplet 104 is disposed in the cavity 212 and mounted on the sacrificial glass carrier 202.

At 414, an electrical and photonic integrated circuit (EPIC) is disposed on the plurality of dielectric layers and the glass chiplet. In certain embodiments, the EPIC 110 is disposed on the dielectrics 118 and the glass chiplet 104. At 416, the carrier is removed from the mold material, the glass chiplet, and the silicon bridge. In some embodiments, the sacrificial glass carrier 202 is removed from the first mold 120, the glass chiplet 104, and the silicon bridge 114. At 418, the mold material, the glass chiplet, and the silicon bridge are mounted on a substrate. In various embodiments, the interposer structure 103 is mounted on the substrate 102.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

While the foregoing is directed to specific examples, other and further examples may be devised without departing from the basic scope thereof, and the scope thereof is determined by the claims that follow.

What is claimed is:

1. Integrated photonics circuitry comprising:
a substrate;
an interposer structure mounted on the substrate, the interposer structure including a glass chiplet;
an electrical and photonic integrated circuit (EPIC) having a first portion disposed on the glass chiplet and a second portion disposed over the substrate; and
a waveguide of the glass chiplet, the waveguide coupled to the EPIC.

2. The integrated photonics circuitry of claim 1, wherein the waveguide is edge coupled to the EPIC.

3. The integrated photonics circuitry of claim 1, wherein the waveguide is fabricated in the glass chiplet using ion exchange.

4. The integrated photonics circuitry of claim 1, further comprising:
a die attach adhesive disposed between the substrate and the glass chiplet.

5. The integrated photonics circuitry of claim 1, further comprising:
solder connections disposed between the substrate and the glass chiplet.

6. The integrated photonics circuitry of claim 1, further comprising:
a mold material disposed between the EPIC and the substrate.

7. The integrated photonics circuitry of claim 6, further comprising:
a plurality of dielectric electric layers disposed between the mold material and the EPIC; and
routing circuitry formed through the plurality of dielectric electric layers and electrically coupled to the EPIC.

8. The integrated photonics circuitry of claim 7, further comprising an underfill epoxy disposed between the EPIC and the plurality of dielectric electric layers.

9. The integrated photonics circuitry of claim 7, further comprising:
a processor disposed over the interposer structure, the processor electrically coupled to the EPIC through the routing circuitry.

10. The integrated photonics circuitry of claim 9, further comprising:
a silicon bridge disposed between the processor and the substrate, the processor electrically coupled to the EPIC through the silicon bridge.

11. The integrated photonics circuitry of claim 1, wherein the waveguide is evanescently coupled to the EPIC.

12. An integrated circuit (IC) package comprising:
a substrate;
an interposer structure mounted on a substrate, the interposer structure comprising:
a glass chiplet;
a silicon bridge;
a plurality of dielectric electric layers disposed on the silicon bridge and having routing circuitry formed therethrough; and
a wave guide;
a processor disposed over the interposer structure; and
an electrical and photonic integrated circuit (EPIC), the EPIC disposed over the interposer structure adjacent the processor and on the glass chiplet, the EPIC and the processor electrically coupled by the routing circuitry and the silicon bridge, the waveguide edge coupled to the EPIC.

13. The IC package of claim 12, wherein the silicon bridge is circumscribed by mold material, the mold material disposed between the plurality of dielectric electric layers and the substrate.

14. The IC package of claim 13, further comprising:
pillars formed through the mold material, the pillars electrically coupling the routing circuitry to the substrate.

15. The IC package of claim 13, wherein the mold material contacts a side of the glass chiplet.

16. The IC package of claim 12, wherein the waveguide is edge coupled to a side portion or bottom portion of the EPIC.

17. A method comprising:
coupling a silicon bridge to a carrier;
forming conductive pillars on the carrier;
disposing a mold material on the carrier around the conductive pillars and the silicon bridge;
forming routing circuitry in a plurality of dielectric layers disposed on the mold material;
removing a portion of the plurality of dielectric layers to expose a portion of the carrier;
mounting a glass chiplet on the portion of the carrier; and
disposing an electrical and photonic integrated circuit (EPIC) on the plurality of dielectric layers and the glass chiplet;
removing the carrier from the mold material, the glass chiplet, and the silicon bridge; and
mounting the mold material, the glass chiplet, and the silicon bridge on a substrate.

18. The method of claim 17, further comprising:
disposing a processor on the plurality of dielectric layers adjacent the EPIC, the processor coupled to the EPIC via the silicon bridge.

19. The method of claim 17, wherein the mold material, the glass chiplet, and the silicon bridge form an interposer structure.

20. The method of claim 17, wherein mounting the glass chiplet on the substrate further comprises:
mounting the glass chiplet on an underfill epoxy and/or solder connections with a die attach adhesive.
